(19) United States
(12) Patent Application Publication
(10) Pub. No.: US 2010/0307583 A1
(43) Pub. Date: Dec. 9, 2010

(54) SOLAR CELL AND METHOD FOR MANUFACTURING THE SAME

(75) Inventor: Mitsuhiro Matsumoto, Gifu-shi (JP)

Correspondence Address: DITTHAVONG MORI & STEINER, P.C., 918 Prince Street, Alexandria, VA, 22314, US

(73) Assignee: SANYO ELECTRIC CO., LTD., Moriguchi-shi (JP)

(21) Appl. No.: 12/750,183

(22) Filed: Mar. 30, 2010

(30) Foreign Application Priority Data
Jun. 4, 2009 (JP) 2009-135397

(51) Int. Cl. H01L 31/0376; H01L 31/18

(52) U.S. Cl. 136/258; 438/93; 257/E31.023

(57) ABSTRACT

A solar cell comprises an amorphous silicon solar cell unit in which a p-type layer, an i-type layer, and an n-type layer are laminated. The p-type layer includes a high-concentration amorphous silicon carbide layer doped with a p-type dopant and an amorphous silicon buffer layer which is substantially undoped with the p-type dopant. Then, a band gap of the amorphous silicon buffer layer is defined to be 1.65 eV or greater.

### CROSS-REFERENCE TO RELATED APPLICATION

The entire disclosure of Japanese Patent Application No. 2009-135397 filed on Jun. 4, 2009 including specification, claims, drawings and abstract is incorporated herein by reference in its entirety.

### BACKGROUND OF THE INVENTION

1. Field of the Invention

The present invention relates to a solar cell and a method for manufacturing the solar cell.

2. Description of the Related Art

Solar cells using polycrystalline, microcrystalline, or amorphous silicon have been known. In particular, solar cells having a laminated structure consisting of microcrystalline or amorphous silicon thin films have attracted attention in terms of resource consumption, cost reduction, and improvement in efficiency.

In general, a thin-film solar cell is formed by sequentially laminating a first electrode, one or more semiconductor thin-film photoelectric conversion cells, and a second electrode on a substrate whose surface has insulating properties. Each solar cell unit is composed of a p-type layer, an i-type layer, and an n-type layer laminated in that order from a light incident side.

Further, as a method for enhancing conversion efficiency in the thin-film solar cell, it has been known that two or more different types of photoelectric conversion cells are laminated along a light incident direction. A first solar cell unit including a photoelectric conversion layer which has a wider band gap is disposed on a light incident side of the thin-film solar cell, and after that, a second solar cell unit including a photoelectric conversion layer which has a band gap narrower than that of the first solar cell unit is disposed thereon. In this manner, incident light having a wide range of wavelengths can be photoelectrically converted, to thereby yield an improvement in overall conversion efficiency of the unit.

For example, there has been known a structure in which an amorphous silicon (a-Si) solar cell unit is disposed as a top cell while a microcrystalline silicon (μc-Si) solar cell unit is disposed as a bottom cell.

Meanwhile, to realize the improvement in conversion efficiency of the thin-film solar cell, each property of the thin films constituting a solar cell should be optimized with the aim of increasing an open circuit voltage Voc, a short-circuit current density Jsc, and a fill factor FF.

### SUMMARY OF THE INVENTION

In one aspect, the present invention provides a solar cell comprising a p-type layer, an i-type amorphous silicon layer laminated on the p-type layer, and an n-type silicon layer laminated on the i-type amorphous silicon layer. In the solar cell, the p-type layer includes a high-concentration amorphous silicon carbide layer doped with a p-type dopant, and an amorphous silicon buffer layer which is substantially undoped with the p-type dopant and formed in a region closer to the i-type amorphous silicon layer than the high-concentration amorphous silicon carbide layer. Further, a band gap of the amorphous silicon buffer layer is 1.65 eV or greater.

### BRIEF DESCRIPTION OF THE DRAWINGS

A preferred embodiment of the present invention will be described in detail based on the following figures, wherein:

FIG. 1 shows a configuration of a tandem solar cell according to an embodiment of the present invention, and

FIG. 2 shows a configuration of an a-Si unit in the tandem solar cell according to the embodiment of the present invention.

### DESCRIPTION OF THE PREFERRED EMBODIMENT

### Basic Configuration

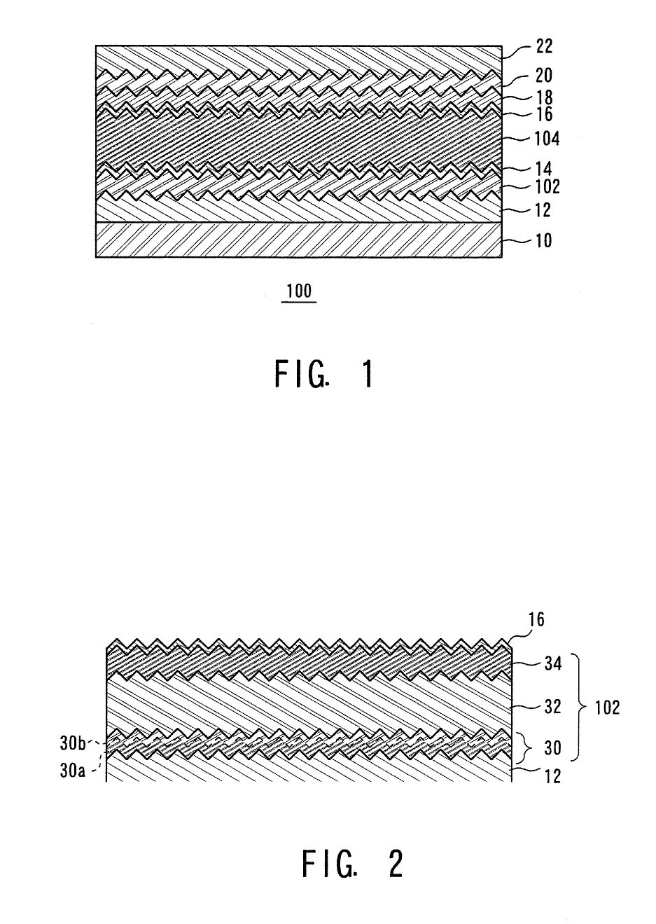

FIG. 1 is a cross sectional view showing a configuration of a tandem solar cell 100 according to an embodiment of the present invention. The tandem solar cell 100 in this embodiment is configured on a transparent insulating substrate 10, which is established as a light incident side, by laminating, from the light incident side, a transparent conductive film 12, an amorphous silicon (a-Si) (photoelectric conversion) unit 102 functioning as a top cell and having a wider band gap, an intermediate layer 14, a microcrystalline silicon (μc-Si) (photoelectric conversion) unit 104 functioning as a bottom cell and having a band gap which is narrower than that of the a-Si unit 102, a first back electrode layer 16, a second back electrode layer 18, a filler 20, and a protective film 22.

The configuration and a manufacturing method of the tandem solar cell 100 according to the embodiment of the present invention will be described below. In this embodiment of the present invention, because the tandem solar cell 100 is particularly characterized by a p-type layer contained in the a-Si unit 102, the p-type layer contained in the a-Si unit 102 will be described in greater detail.

The transparent insulating substrate 10 may be composed of a material, such as, for example, a glass substrate or a plastic substrate, which is transparent to light of wavelengths at least in a visible light range. The transparent conductive film 12 is formed on the transparent insulating substrate 10. It is preferable for the transparent conductive film 12 to be formed using at least one of, or a combination of, two or more transparent conductive oxides (TCO), such as a tin oxide (SnO₂), a zinc oxide (ZnO), and an indium tin oxide (ITO), doped with tin (Sn), antimony (Sb), fluorine (F), aluminum (Al), or the like. In particular, the zinc oxide (ZnO) which has high transparency and low resistivity as well as excellent plasma resistance properties is particularly preferable. The transparent conductive film 12 may be formed, for example, by means of sputtering or other techniques. A film thickness of the transparent conductive film 12 is preferably in the range of from 0.5 μm to 5 μm. It is also preferable that asperities having an optical confinement effect are formed on the surface of the transparent conductive film 12.

A p-type layer 30, an i-type layer 32, and an n-type layer 34 which are thin films of silicon series are sequentially laminated on the transparent conductive film 12 to form the a-Si unit 102. FIG. 2 is an enlarged cross sectional view showing a part of the a-Si unit 102.

The a-Si unit 102 may be formed by means of plasma CVD in which film formation is performed using a plasma produced from a mixed gas consisting of a silicon-containing gas such as silane (SiH₄), disilane (Si₂H₆), or dichlorosilane (SiH Cl₂); a carbon-containing gas such as methane (CH₄); a p-type dopant-containing gas such as diborane (B₂H₆); an n-type dopant-containing gas such as phosphine (PH₃); and a diluent gas such as hydrogen (H₂).

As the plasma CVD, for example, RF plasma CVD using a frequency of 13.56 MHz may be preferably employed. The RF plasma CVD may be implemented using a plasma device of a parallel plate type. One of the parallel plate electrodes on which the transparent insulating substrate 10 is not located may be provided with outlet ports for gas shower to supply a source mixed gas. Preferably, a plasma discharge power density is specified to 5 mW/cm² or greater but not more than 100 mW/cm².

In general, the p-type layer 30, the i-type layer 32, and the n-type layer 34 are separately formed in different film forming chambers. The film forming chambers can be evacuated by means of a vacuum pump, and configured so as to incorporate electrodes used for the RF plasma CVD. In addition, an apparatus for transporting the transparent insulating substrate 10, a power source and a matching unit for the RF plasma CVD, a pipe arrangement for gas feeding, and other units are equipped.

The p-type layer 30 is formed on the transparent conductive film 12. Firstly, an amorphous silicon carbide layer 30a doped with a p-type dopant (such as boron) is formed on the transparent conductive film 12. After that, an amorphous silicon buffer layer 30b which is not doped with the p-type dopant (such as boron) is formed on the amorphous silicon carbide layer 30a. More specifically, the plasma of the mixed gas consisting of the silicon-containing gas, the carbon-containing gas, the p-type dopant-containing gas, and the diluent gas is generated to perform film formation of the amorphous silicon carbide layer 30a. It is preferable to use the high-concentration amorphous silicon carbide layer 30a which is formed on condition that a flow rate of diborane (B2H6) is 0.5% that of silane (SiH4), or higher. Then, a plasma of a mixed gas consisting of the silicon-containing gas and the diluent gas is generated to perform film formation of the amorphous silicon buffer layer 30b undoped with the p-type dopant (such as boron).

Here, it is preferable for the amorphous silicon buffer layer 30b to be constructed as a layer having a band gap of 1.65 eV or greater. When the thus-constructed amorphous silicon buffer layer 30b is used, a resistance loss in the solar cell can be reduced, to thereby increase the fill factor FF. It is further achieved that the solar cell becomes less prone to a photo-degradation effect than is obtained in a case of using a silicon carbide layer or other layers as the buffer layer.

In this embodiment, sequential formation of the high-concentration amorphous silicon carbide layer 30a and the amorphous silicon buffer layer 30b can be realized by adjusting a mixing ratio of the silicon-containing gas, the carbon-containing gas, the p-type dopant-containing gas, and the diluent gas in addition to adjusting a pressure and high-frequency power for plasma generation, while maintaining the plasma generated in the plasma CVD. In this way, formation of an initial layer at the beginning of plasma generation, which has a detrimental effect on power generation, can be prevented from occurring at an interface between the high-concentration amorphous silicon carbide layer 30a and the amorphous silicon buffer layer 30b. As a result, the open-circuit voltage Voc and the fill factor FF of the solar cell can be increased.

After the formation of the high-concentration amorphous silicon carbide layer 30a, the plasma may be shut off, of course, in order to adjust the mixing ratio of the silicon-containing gas, the carbon-containing gas, the p-type dopant-containing gas, and the diluent gas in addition to adjusting the pressure and the high frequency power for plasma generation. Subsequent to the adjustment, generation of plasma may be resumed to form the amorphous silicon buffer layer 30b. This method of formation is advantageous in that a doping concentration can be abruptly changed at the interface between the high-concentration amorphous silicon carbide layer 30a and the amorphous silicon buffer layer 30b. In particular, effects of the p-type dopant-containing gas remaining in the film forming chamber can be eliminated by evacuating a film forming apparatus before adjusting the mixing ratio of the gases.

Further, with respect to the formation of the amorphous silicon buffer layer 30b, after the high-concentration amorphous silicon carbide layer 30a is formed, the transparent insulating substrate 10 may be moved, to form the amorphous silicon buffer layer 30b, into the film forming chamber intended for use in formation of the i-type layer 32. As such, when the amorphous silicon buffer layer 30b is formed in the film forming chamber which is not supplied with the p-type dopant-containing gas, an abrupt change in doping concentration between the doped high-concentration amorphous silicon carbide layer 30a and the undoped amorphous silicon buffer layer 30b can be realized to thereby reduce a defect density at the interface between the high-concentration amorphous silicon carbide layer 30a and the amorphous silicon buffer layer 30b. In this way, the open-circuit voltage Voc of the solar cell can be enhanced.

The i-type layer 32 is configured as an undoped amorphous silicon layer formed on the p-type layer 30 with a film thickness of 50 nm or greater but no more than 500. Film quality of the i-type layer 32 may be changed by adjusting the mixing ratio of the silicon-containing gas and the diluent gas in addition to adjusting the pressure and the high-frequency power for plasma generation. Further, the i-type layer 32 functions as a power generation layer in the a-Si unit 102. The n-type layer 34 is configured as an n-type amorphous silicon layer (n-type α-Si:H) or an n-type microcrystalline silicon layer (n-type μc-Si:H), which is doped with an n-type dopant (such as phosphor), and formed on the i-type layer 32 with a film thickness of 10 nm or greater but no more than 100 nm. The film quality of the n-type layer 34 may be changed by adjusting the mixing ratio of the silicon-containing gas, the carbon-containing gas, the n-type dopant-containing gas, and the diluent gas in addition to adjusting the pressure and the high-frequency power for plasma generation.

The intermediate layer 14 is formed on the a-Si unit 102. A transparent conductive oxide (TOC), such as a zinc oxide (ZnO) or a silicon oxide (SiOx), may be preferably used for the intermediate layer 14. It is particularly preferable to use the zinc oxide (ZnO) or the silicon oxide (SiOx) doped with magnesium (Mg). The intermediate layer 14 may be formed by, for example, sputtering or other techniques. Preferably, the film thickness of the intermediate layer 14 is in the range of from 10 nm to 200 nm. It should be noted that the intermediate layer 14 may be omitted.

The μc-Si unit 104 obtained by sequentially laminating the p-type layer, the i-type layer, and the n-type layer is formed on the intermediate layer 14. The μc-Si unit 104 may be formed by means of the plasma CVD in which film formation is performed using the plasma produced from the mixed gas consisting of the silicon-containing gas such as silane (SiH₄), disilane (Si₂H₆), or dichlorosilane (SiH Cl₂); the carbon-containing gas such as methane (CH₄); the p-type dopant-containing gas such as diborane (B₂H₆); the n-type dopant-containing gas such as phosphine (PH₃); and the diluent gas such as hydrogen (H₂).

As the plasma CVD, similarly to the a-Si unit 102, the RF plasma CVD using the frequency of 13.56 MHz may be preferably employed. The RF plasma CVD may be implemented using the plasma device of the parallel plate type. One of the parallel plate electrodes on which the transparent insulating substrate 10 is not located may be provided with outlet ports for gas shower to supply the source mixed gas. It is preferable for the plasma discharge power density to be specified to 5 mW/cm² or greater but no more than 100 mW/cm².

The μc-Si unit 104 is configured by laminating, for example, a p-type microcrystalline silicon layer (p-type μc-Si:H) doped with boron and having a film thickness of 5 nm or greater but no more than 50 nm, an undoped i-type microcrystalline silicon layer (i-type μc-Si:H) having a film thickness of 0.5 μm or greater but no more than 5 μm, and an n-type microcrystalline silicon layer (n-type μc-Si:H) doped with phosphor and having the film thickness of 5 nm or greater but no more than 50 nm.

However, the unit on the intermediate layer 14 is not limited to the above-described μc-Si unit 104, and may be any unit in which the i-type microcrystalline silicon layer (i-type pc-Si:H) is used as the power generation layer.

On the μc-Si unit 104, a laminated structure of reflective metal and the transparent conductive oxide (TCO) is formed as the first back electrode layer 16 and the second back electrode layer 18. A metal, such as silver (Ag) or aluminum (Al), may be used for the first back electrode layer 16. On the other hand, the transparent conductive oxide such as the tin oxide (SnO₂), the zinc oxide (ZnO), or the indium tin oxide (ITO), may be used for the second back electrode layer 18. The TCO may be formed by, for example, sputtering or other techniques. It is preferable for the first back electrode layer 16 and the second back electrode layer 18 to have a combined film thickness of approximately 1 μm. At least one of the first and second back electrode layers 16 and 18 is preferably provided with the asperities to enhance the optical confinement effect.

Further, a surface of the second back electrode layer 18 is covered with the protective film 22 using the filler 20. The filler 20 and the protective film 22 may be composed of a resin material such as EVA or polyimide. In this way, the power generation layer of the tandem solar cell 100 can be protected against moisture intrusion or the like.

It should be noted that processing for separating the transparent conductive film 12, the a-Si unit 102, the intermediate layer 14, the μc-Si unit 104, the first back electrode layer 16, and the second back electrode layer 18 may be performed using a YAG laser (a fundamental wave with a wavelength of 1064 nm, a double wave with a wavelength of 532 nm) to realize a configuration in which a plurality of cells are connected in series.

Up to this point, the basic configuration of the tandem solar cell 100 according to the embodiment of the present invention has been described. Hereinafter, a configuration of the p-type layer 30 will be described with reference to examples.

### Example

An example of the tandem solar cell 100 in which the p-type layer 30 according to the above-described embodiment is applied and a comparison example will be described below.

A glass substrate which was a rectangle of 33 cm×43 cm and was 4 mm in thickness was used as the transparent insulating substrate 10. On the transparent insulating substrate 10, an

SnO₂ film having a thickness of 60 nm and having a surface shaped with asperities was formed through thermal CVD as the transparent conductive film 12. Then, the transparent conductive film 12 was patterned into strip shapes by means of the YAG laser. For the YAG laser, laser light having a wavelength of 1064 nm, an energy density of 13 J/cm³, and a pulse frequency of 3 kHz was used.

Next, the high-concentration amorphous silicon carbide layer 30a and the amorphous silicon buffer layer 30b were formed under film forming conditions specified in Table 1. Note that Table 1 also includes, as Comparison Example 1, the conditions applied to a case where a microcrystalline silicon carbide layer was formed in place of the amorphous silicon buffer layer 30b. The i-type layer 32 and the n-type layer 34 in the a-Si unit 102 were formed under the film forming conditions indicated in Table 2, while the p-type layer, the i-type layer, and the n-type layer in the μc-Si unit 104 were formed under the conditions indicated in Table 3.

TABLE 1

| | Substrate | Gas | Reaction | RF |
|---|---|---|---|---|
| | Temperature | Flow Rate | Pressure | power |
| Layer | (° C.) | (sccm) | (Pa) | (W) |
| High-concentration | 180 | SiH₄: 40 | 80 | 30 |
| Amorphous Silicon | | CH₄: 80 | | |
| Carbide Layer 30a | | B₂H₆: 0.12 | | |
| | | H₂: 400 | | |
| Amorphous Silicon | 180 | SiH₄: 20 | 80 | 30 |
| Buffer Layer 30b | | H₂: 600 | | |
| Microcrystalline | 180 | SiH₄: 20 | 80 | 30 |
| Silicon Carbide Layer | | CH₄: 10 | | |
| | | H₂: 2000 | | |

TABLE 2

| | Substrate | Gas | Reaction | RF | Film |
|---|---|---|---|---|---|
| | Temperature | Flow Rate | Pressure | Power | Thickness |
| Layer | (° C.) | (sccm) | (Pa) | (W) | (nm) |
| i-Type Layer | 200 | SiH₄: 300 | 106 | 20 | 250 |
| | | H₂: 2000 | | | |
| n-Type | 180 | SiH₄: 300 | 133 | 20 | 25 |
| Layer | | H₂: 2000 | | | |
| | | PH₃: 5 | | | |

TABLE 3

| | Substrate | Gas | Reaction | RF | Film |
|---|---|---|---|---|---|
| | Temperature | Flow Rate | Pressure | Power | Thickness |
| Layer | (° C.) | (sccm) | (Pa) | (W) | (nm) |
| p-Type | 180 | SiH₄: 10 | 106 | 10 | 10 |
| Layer | | H₂: 2000 | | | |
| | | B₂H₆: 3 | | | |
| i-Type Layer | 200 | SiH₄: 100 | 133 | 20 | 2000 |
| | | H₂: 2000 | | | |
| n-Type | 200 | SiH₄: 10 | 133 | 20 | 20 |
| Layer | | H₂: 2000 | | | |
| | | PH₃: 5 | | | |

Thereafter, a position laterally shifted by 50 μm from a patterning position of the transparent conductive film 12 was irradiated with the YAG laser, to thereby pattern the a-Si unit 102 and the μc-Si unit 104 into the strap shapes. Laser light having the energy density of 0.7 J/cm³ and the pulse frequency of 3 kHz was used as the YAG laser.

Next, an Ag electrode was formed as the first back electrode layer 16 through sputtering, while a ZnO film was formed as the second back electrode layer 18 through sputtering. Subsequent to the formation, the YGA laser was applied to a position laterally shifted by 50 μm from the patterning position of the a-Si unit 102 and the μc-Si unit 104, to thereby pattern the first back electrode layer 16 and the second back electrode layer 18 into the strip shape. Laser light having the energy density of 0.7 J/cm³ and a pulse frequency of 4 kHz was used as the YAG laser.

Then, the high-concentration amorphous silicon carbide layer 30a and the amorphous silicon buffer layer 30b were formed into films having the film thicknesses indicated in Table 4, which was defined as Example 1. On the other hand, as Comparison Example 1, the microcrystalline silicon carbide layer was formed directly on the high-concentration amorphous silicon carbide layer 30a without forming the amorphous silicon buffer layer 30b.

TABLE 4

| | High-concentration | Amorphous | |
|---|---|---|---|
| | Amorphous Silicon | Silicon | Microcrystalline |
| | Carbide Layer | Buffer Layer | Silicon Carbide |
| | 30a | 30b | Layer |
| Example 1 | 7 nm | 10 nm | None |
| Comparison | 10 nm | None | 10 nm |
| Example 1 | | | |

Table 5 shows initial characteristics of the open-circuit voltage Voc, the short-circuit current density Jsc, the fill factor FF, and efficiency of the tandem solar cells 100 of Example 1 and Comparison Example 1. Further, Table 6 shows the open-circuit voltage Voc, the short-circuit current density Jsc, the fill factor FF, and the efficiency which were stabilized after 5-hour use of the tandem solar cells 100 of Example 1 and Comparison Example 1 at 48° C. and at 5-sun illumination. The band gap Eₒₚₜ of the amorphous silicon buffer layer 30b can be found by a method described below. After an absorption coefficient spectrum of the amorphous silicon buffer layer 30b is found, an optical band gap Eₒₚₜ is determined from an (αhν)^{1/3} plot based on the absorption coefficient spectrum as described, for example, in “Japanese Journal of Applied Physics Vol. 30, No. 5, May, 1991, pp. 1008-1014”. Measurement of transmittance and reflectance used for finding the absorption coefficient spectrum may be performed using, for example, Spectrophotometer U-4100 manufactured by Hitach High-Technologies Corporation. Further, when the absorption coefficient spectrum is found, it is preferable to evaluate a film formed with a thickness of from 100 nm to 300 nm on a glass substrate under the same conditions as those applied to formation of a solar cell element. In addition, the glass substrate used for forming the film may be Corning 7059 Glass, Corning 1737 Glass, or a whiteboard glass of a thickness of 5 mm or less.

TABLE 5

| | Open-Circuit | Short-Circuit | | |
|---|---|---|---|---|
| | Voltage | Current Density | | Efficiency |
| | Voc (V) | Jsc (A/cm²) | FF | η (%) |
| Example 1 | 0.98 | 1 | 1.04 | 1.02 |
| Comparison | 1 | 1 | 1 | 1 |
| Example 1 | | | | |

TABLE 6

| | Open-Circuit | Short-Circuit | | |
|---|---|---|---|---|
| | Voltage | Current Density | | Efficiency |
| | Voc (V) | Jsc (A/cm²) | FF | η (%) |
| Example 1 | 0.99 | 1 | 1.05 | 1.04 |
| Comparison | 1 | 1 | 1 | 1 |
| Example 1 | | | | |

When the p-type layer 30 in which the high-concentration amorphous silicon carbide layer 30a and the amorphous silicon buffer layer 30b are laminated is used as achieved in Example 1, even though the open-circuit voltage Voc is reduced, the fill factor FF is increased. As a result, the overall efficiency η of the tandem solar cell 100 is increased relative to that of Comparative Example 1. It is conceivable that the increase is brought about by reduction in resistance loss of the p-type layer 30.

Moreover, the characteristics obtained after the stabilization are severely deteriorated in Comparison Example 1, whereas deterioration of the characteristics is alleviated in Example 1. Further, in the characteristics after the stabilization, a difference of the open-circuit voltages Voc between Example 1 and Comparative Example 1 is reduced, while a rate of increase in the fill factor FF of Example 1 relative to that of Comparative Example is improved. Consequently, the overall efficiency η of the tandem solar cell 100 is further improved in Example 1 relative to that in Comparative Example 1.

What is claimed is:

1. A solar cell comprising:
a p-type layer, an i-type amorphous silicon layer laminated on the p-type layer, and an n-type silicon layer laminated on the i-type amorphous silicon layer; wherein
the p-type layer comprises a high-concentration amorphous silicon carbide layer doped with a p-type dopant, and an amorphous silicon buffer layer which is substantially undoped with the p-type dopant and formed in a region closer to the i-type amorphous silicon layer than the high-concentration amorphous silicon carbide layer, and
a band gap of the amorphous silicon buffer layer is 1.65 eV or greater.

2. A method for manufacturing a solar cell, comprising:
a first step of forming a p-type layer;
a second step of forming an i-type amorphous silicon layer laminated on the p-type layer, and
a third step of forming an n-type silicon layer doped with an n-type dopant and laminated on the i-type amorphous silicon layer, wherein
the first step further comprises a step of forming a high-concentration amorphous silicon carbide layer doped with a p-type dopant, and a step of forming an amorphous silicon buffer layer which is substantially undoped with the p-type dopant and formed in a region closer to the i-type amorphous silicon layer than the high-concentration amorphous silicon carbide layer, the amorphous silicon buffer layer having a band gap of 1.65 eV or greater.

3. A method for manufacturing a solar cell according to claim 2, wherein
the first and second steps are performed using a silicon-containing gas and a hydrogen gas, and
a flow rate of the silicon-containing gas and the hydrogen gas used in the step of forming the amorphous silicon buffer layer included in the first step is lower than that used in the second step.
